(19) United States
(12) Patent Application Publication
(10) Pub. No.: US 2018/0045791 A1
(43) Pub. Date: Feb. 15, 2018

(54) POWER SUPPLY CONDITION MONITOR

(71) Applicant: SIKORSKY AIRCRAFT CORPORATION, Stratford, CT (US)

(72) Inventors: Patrick W. Kalgren, Conesus, NY (US); Kenneth Gravenstede, Lima, NY (US)

(21) Appl. No.: 15/556,544

(22) PCT Filed: Jan. 14, 2016
(86) PCT No.: PCT/US16/13428

§ 371 Date: Sep. 7, 2017

Related U.S. Application Data
(60) Provisional application No. 62/133,675, filed on Mar. 16, 2015.

(51) Int. Cl. G01R 31/40; B64D 45/00

(52) U.S. Cl. CPC G01R 31/40; B64D 45/00; B64C 27/10

(57) ABSTRACT

A method for monitoring a health state of electronic equipment is provided and includes capturing data of an operation of the electronic equipment over a sampling range of predefined length, storing captured data in a storage unit and characterizing a behavior of the operation of the electronic equipment based on an analysis of stored captured data in an event a predefined time has expired or the storage unit has reached maximum capacity.

### CROSS-REFERENCE TO RELATED APPLICATION

This invention is related to the disclosure of U.S. Pat. No. 8,103,463, which issued on Jan. 24, 2015. The entire disclosures of U.S. Pat. No. 8,103,463 are incorporated herein by reference.

### FEDERAL RESEARCH STATEMENT

This invention was made with government support under Contract No. W911W6-08-C-0053 awarded by the Army. The government has certain rights in the invention.

### BACKGROUND OF THE INVENTION

The subject matter disclosed herein relates to a monitor and, more particularly, to an online power supply condition monitor.

During normal operations of electronic equipment, power supplies convert and condition source power to a signal that is useful and protective for the supplied electronic system. However, undetected degradation of power supplies can result in catastrophic failure that can be damaging to the supplied system and other source connected electronic systems. Thus, current technology for detecting degradation of power supplies relates to systems and methods for detecting degradation (prior to functional failure) of power supplies and for predicting remaining useful life prior to functional and catastrophic failures. Such systems and methods generally operate within a testing environment but do not address degradation detection within an operational environment.

### BRIEF DESCRIPTION OF THE INVENTION

According to one aspect of the invention, a method for monitoring a health state of electronic equipment is provided and includes capturing data of an operation of the electronic equipment over a sampling range of predefined length, storing captured data in a storage unit and characterizing a behavior of the operation of the electronic equipment based on an analysis of stored captured data in an event a predefined time has expired or the storage unit has reached maximum capacity.

In accordance with additional or alternative embodiments, the capturing includes collecting current and voltage samples at an input and an output of a power supply of the electronic equipment.

In accordance with additional or alternative embodiments, the capturing includes data sampling.

In accordance with additional or alternative embodiments, the capturing is conducted by sensors embedded in the electronic equipment.

In accordance with additional or alternative embodiments, the capturing is conducted by sensors disposed externally with respect to the electronic equipment.

In accordance with additional or alternative embodiments, the electronic equipment includes a power converter.

In accordance with additional or alternative embodiments, the method further includes deferring the characterizing until the predefined time expires or the storage unit reaches the maximum capacity.

In accordance with additional or alternative embodiments, the characterizing includes characterizing a behavior of input versus output power in the electrical equipment.

According to another aspect of the invention, a method for monitoring a health state of electronic equipment of a rotorcraft is provided. The method includes capturing current and voltage samples from an input power and an output power of a power converter of the electronic equipment over a sampling range of predefined length, storing data reflective of the captured current and voltage samples in a storage unit having a maximum capacity, deferring a characterization of the stored data until a predefined time expires or the storage unit reaches the maximum capacity and characterizing a behavior of the input power and the output power based on an analysis of the stored data in an event the predefined time has expired or the storage unit has reached the maximum capacity.

In accordance with additional or alternative embodiments, the capturing is conducted by one or both of sensors embedded in the power converter and sensors disposed externally with respect to the power converter.

According to another aspect of the invention, a rotorcraft is provided and includes an airframe on which main and auxiliary rotors are operably disposed to be drivable to rotate relative to the airframe to generate lift and thrust, electronic equipment disposed about the airframe, an electronic power supply disposed to provide electric power to the electronic equipment and a power supply control system coupled to the electronic power supply to control a provision of the electric power to the electronic equipment. The power supply control system includes a processing system to execute the methods for monitoring a health state of electronic equipment.

In accordance with additional or alternative embodiments, the power supply control system includes a power converter.

In accordance with additional or alternative embodiments, the processing system is embedded in the power converter.

In accordance with additional or alternative embodiments, the processing system is disposed externally with respect to the power converter.

In accordance with additional or alternative embodiments, the processing system includes a health and usage monitoring system (HUMS).

These and other advantages and features will become more apparent from the following description taken in conjunction with the drawings.

### BRIEF DESCRIPTION OF THE DRAWING

The subject matter, which is regarded as the invention, is particularly pointed out and distinctly claimed in the claims at the conclusion of the specification. The foregoing and other features, and advantages of the invention are apparent from the following detailed description taken in conjunction with the accompanying drawings in which:

FIG. 1 is a side view of a coaxial, counter-rotating rotorcraft;

FIG. 2 is a front, elevation view of the rotorcraft of FIG. 1;

FIG. 3 is a schematic diagram of components of the rotorcraft of FIG. 1;

FIG. 4 is a schematic diagram of a health monitoring system of the rotorcraft of FIGS. 1-3;

FIG. 5 is an illustrative schematic of an electric power converter having an embedded health monitoring system;

FIG. 6 is a block diagram of an exemplary embedded health monitoring system;

FIG. 7 is an illustrative schematic of an electric power converter having an external health monitoring system;

FIG. 8 is a block diagram of an exemplary embedded health monitoring system;

FIG. 9 is a flow diagram illustrating a method for monitoring a health state of electronic equipment.

The detailed description explains embodiments of the invention, together with advantages and features, by way of example with reference to the drawings.

### DETAILED DESCRIPTION OF THE INVENTION

As will be described below, detection of power supply degradation and prediction of remaining useful life prior to functional and catastrophic failures is provided by a system and method of continuous monitoring within an operational environment that overcomes sampling, processing and data management challenges. The system and method provide for aperiodic current and voltage samples to be collected at an input and an output of a monitored power supply, provide input to an embedded processor connected to sensors and include an intelligent data measurement scheme that controls measurement collection to ensure that a sufficient operational range is captured, that minimizes required processing power and optimizes data sampled to available storage and that characterizes the behavior of the input power versus the output power. The system and method further maintain a history to support trend analysis and prediction.

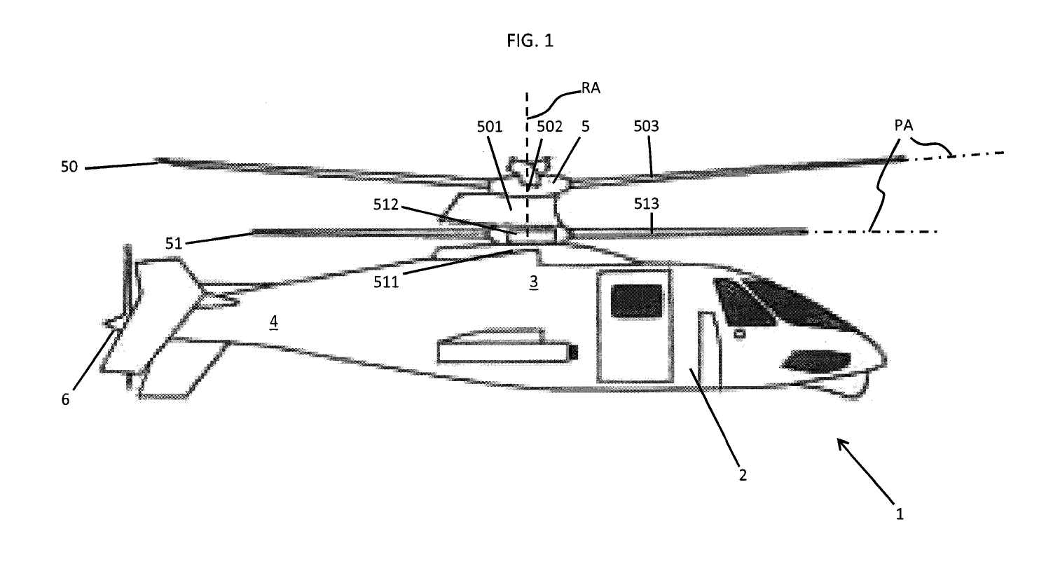

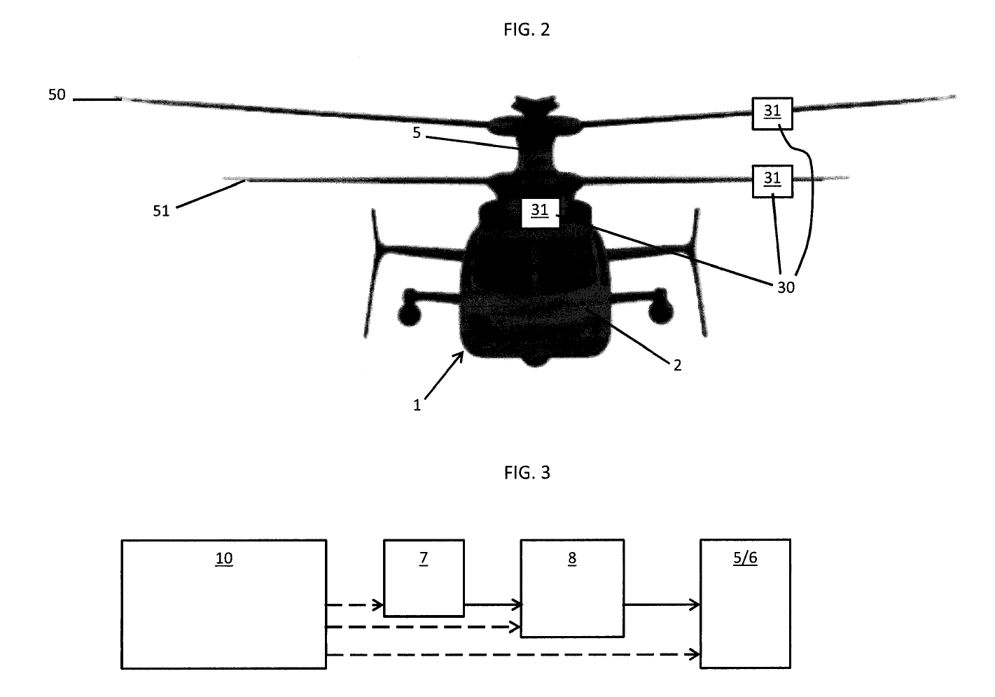

With reference to FIGS. 1-3, a coaxial rotorcraft 1 is provided and may be configured for example as a coaxial, counter-rotating helicopter or some other fixed or variable wing aircraft with single or multiple rotors. The rotorcraft 1 has an airframe 2 that is sized to accommodate a pilot and, in some cases, one or more crewmen and/or passengers as well as control features and a flight computer 10 (see FIG. 3). The airframe 2 has a top portion 3 and a tail portion 4 that extends in the aft direction. The rotorcraft 1 further includes a main rotor assembly 5 at the top portion 3 of the airframe 2, an auxiliary propulsor 6 at the tail portion 4, an engine 7 (see FIG. 3) and a transmission 8 (see FIG. 3). The engine 7 may be disposed within or on the airframe 2 and is configured to generate power to drive respective rotations of the main rotor assembly 5 and the auxiliary propulsor 6. The transmission 8 is similarly disposed within or on the airframe 2 and is configured to transmit the power from the engine 7 to the main rotor assembly 5 and the auxiliary propulsor 6.

The main rotor assembly 5 includes a first or upper rotor 50 and a second or lower rotor 51. The upper rotor 50 includes a rotor shaft 501, a hub 502 and blades 503 extending radially outwardly from the hub 502. The rotor shaft 501 and the hub 502 are rotatable in a first direction about rotational axis RA, which is defined through the airframe 2, to drive rotations of the blades 503 about the rotational axis RA in the first direction. The lower rotor 51 includes a rotor shaft 511, a hub 512 and blades 513 extending radially outwardly from the hub 512. The rotor shaft 511 and the hub 512 are rotatable in a second direction about the rotational axis RA, which is opposite the first direction, to drive rotations of the blades 513 about the rotational axis RA in the second direction. The auxiliary propulsor 6 has a similar structure with an axis of rotation that is generally aligned with a longitudinal axis of the tail portion 4.

The blades 503, 513 are pivotable about respective pitch axes PA that run along respective longitudinal lengths of the blades 503, 513. This pitching can include lateral cyclic pitching, longitudinal cyclic pitching and collective pitching. Lateral cyclic pitching varies blade pitch with left and right movements and tends to tilt the rotor disks formed by the blades 503 and 513 to the left and right to induce roll movements. Longitudinal cyclic pitching varies blade pitch with fore and aft movements and tends to tilt the rotor disks forward and back to induce pitch nose up or down movements. Collective pitching refers to collective angle of attack control for the blades 503, 513 to increase/decrease torque.

When driven to rotate by the engine 7 via the transmission 8, the main rotor assembly 5 generates lift and the auxiliary propulsor 6 generates thrust. The pilot (and crew) and the flight computer 10 can cyclically and collectively control the pitching of the blades 503, 513 of at least the main rotor assembly 5 in order to control the flight and navigation of the rotorcraft 1 in accordance with pilot/crew inputted commands and current flight conditions.

The rotorcraft 1 may also include a system of sensors 30. The system of sensors 30 may include a plurality of individual sensors 31 that are respectively disposed about the airframe 2 on rotating or non-rotating frames. That is, the sensors 31 can be disposed on the hubs 502, 512, the blades 503, 513 or on/in the airframe 2.

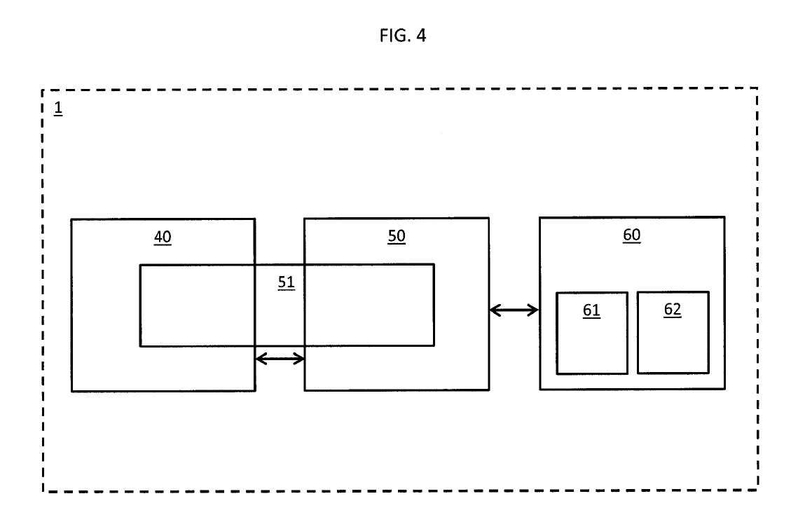

With reference to FIG. 4, the rotorcraft 1 of FIGS. 1-3 may further include electronic equipment 40 disposed about the airframe 2, an electronic power supply 50 disposed to provide electric power to the electronic equipment 40 and a power supply control system 60. The electronic equipment 40 can include the system of sensors 30 or components thereof as well as additional electronic equipment used by the flight computer 10 or other on-board computing or electronic devices. The electronic power supply 50 includes at least a power converter 51 (i.e., an AC-DC power converter). The power converter 51 may be provided as a component of the electrical equipment 40 as well.

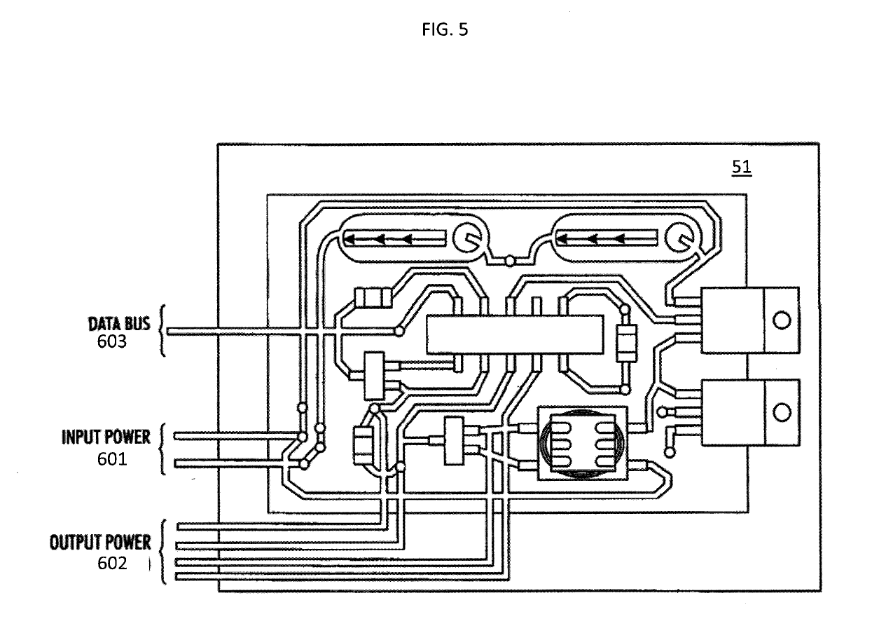

The power supply control system 60 is coupled to the electronic power supply 50 and is configured to control a provision of the electric power to the electronic equipment 40. To this end, the power supply control system 60 includes a processing system 61 that executes the methods described below. With reference to FIGS. 5-8, various hardware configurations or embodiments for the power supply control system 60 exist. These include, but are not limited to the possibility of the power supply control system 60 being a component of a health and usage monitoring system (HUMS).

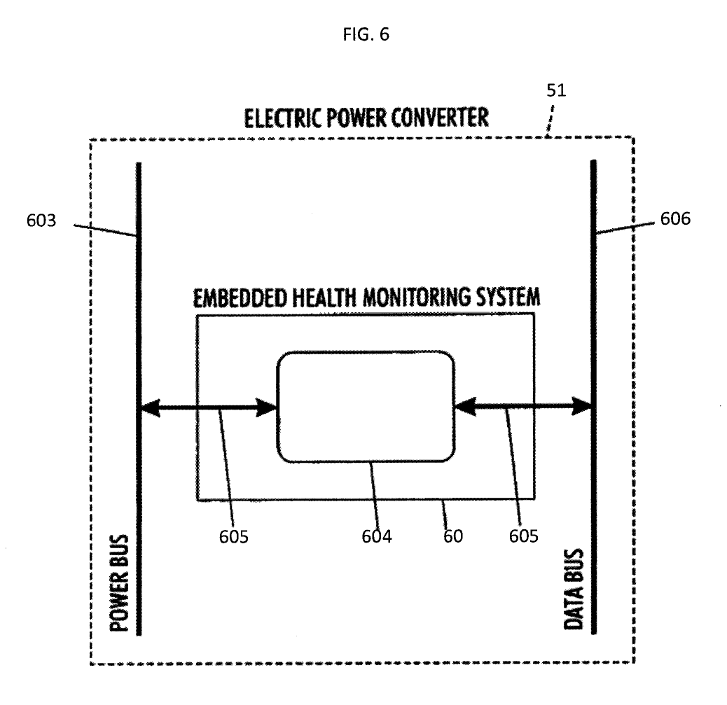

The power supply control system 60 illustrated in FIGS. 5 and 6 utilizes available hardware within the power converter 51, such as sensors, to measure input currents and voltages from input power lines 601 and output currents and voltages at output power lines 602. As shown in FIG. 6, the power supply control system 60 may be embedded in the power converter 51 with an internal power bus 603, which includes the input power lines 601 and the output power lines 602, connected to monitoring unit 604. The monitoring unit 604 includes a digital bus 605 that is connected to a main data bus 606 of the power converter 51.

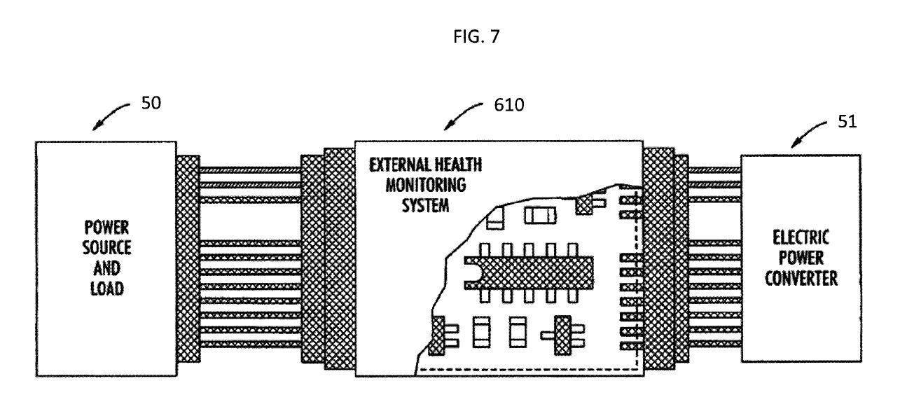

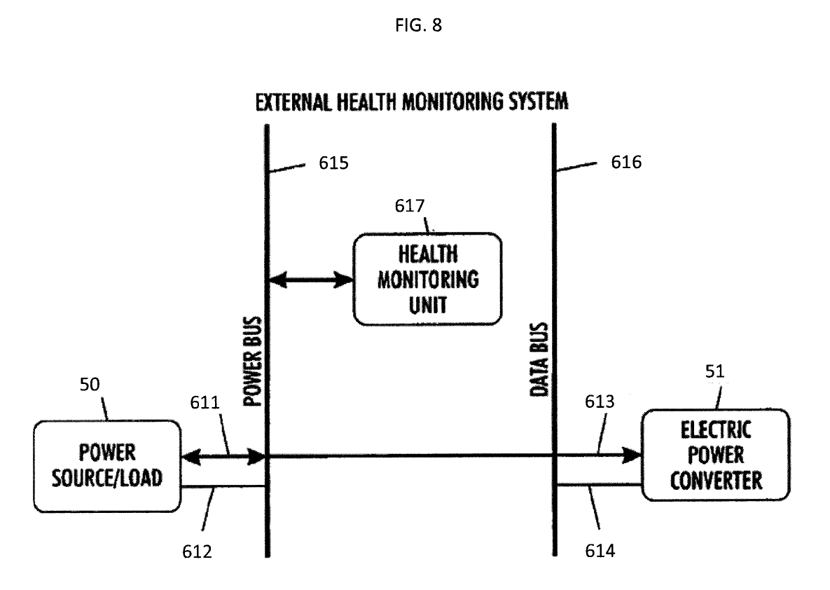

The power supply control system 60 illustrated in FIGS. 7 and 8 can be implemented as a third party module 610 that is connected between the electronic power supply 50 and load and the power converter 51. As shown in FIG. 8, an input power cable for the module 610 includes input power lines 611 and data lines 612, which are wired together with converter power lines 613 and the converter data lines 614. This allows a direct connection between the electronic power supply 50 and load and the power converter 51. Within the module 610, a power bus 615 and data bus 616 are connected to the input power lines 611 and the converter power lines 613, respectively, and to the input data lines 612 and the converter data lines 614, respectively. Both the power bus 615 and the data bus 616 are connected to monitoring unit 617

The monitoring units 604 and 617 used in the embedded and the external embodiments both include sensors to monitor input and output voltages and currents of the power converter 51 where each sensor is used to measure a single electrical quantity. Each sensor includes a transducer to convert either voltage or current to an appropriate electrical signal and a low-pass filter that outputs a signal to an analog-to-digital converter (ADC). The sensors may be a collection of environmental sensors that each acts as a transducer used to measure one or more of the following environmental parameters: temperature, vibration, humidity, radiation and pressure. Each low pass filter is designed to anti-alias the electrical signals measured from the transducer.

The output of each transducer of each sensor is connected to one channel of the ADC. The ADC quantizes all of the sensor values into digital signals and may be connected to a processor 61, which is itself connected a storage unit 62 (see FIG. 4) to store historical health assessment information, performance metrics and trained models. Health assessments generated by the processor 61 can be displayed using visual indicators or sent to a third party. The storage unit 62 has a predefined and known maximum capacity.

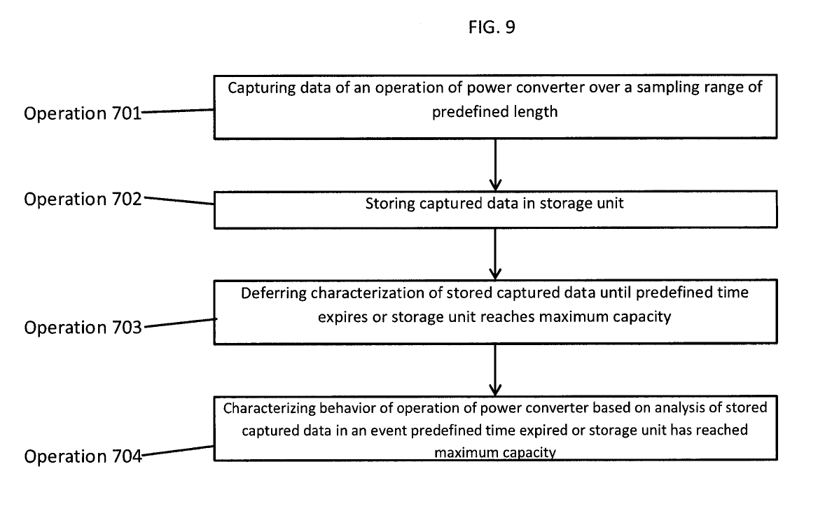

In any case, with reference to FIG. 9, a method for monitoring a health state of the electronic equipment 40 of the rotorcraft 1 or, more particularly, of the power converter 51 is provided. The method includes capturing data of an operation of the power converter 51 over a sampling range of predefined length (operation 701), storing captured data in the storage unit 62 (operation 702), deferring a characterization of the stored captured data until a predefined time expires or the storage unit 62 reaches the maximum capacity thereof (operation 703) and characterizing a behavior of the operation of the power converter 51 based on an analysis of stored captured data in an event the predefined time has expired or the storage unit 62 has reached the maximum capacity (operation 704).

In accordance with embodiments, the capturing of the data of operation 701 may include collecting current and voltage samples at the input and the output of the power converter 51 by way of the sensors of the monitoring units 604 and 617 at data collection sampling rates below 1 sample/second. In addition, the sampling range of the predefined length may be any sampling range that encompasses an operational range sufficient for the collection of the data. Also, the characterizing of operation 704 may include characterizing a behavior of input versus output power in the power converter 51 as disclosed in U.S. Pat. No. 8,103,463. In accordance with alternative embodiments, however, it is to be understood that the data collection sampling rates may be synchronous or asynchronous and may be accomplished at higher rates, perhaps exceeding the above-noted 1 sample/second.

As described herein, failures of power supplies are usually among the top maintenance drivers for electronic systems. Therefore, detection of an impending failure, prior to loss of functionality, can provide for mission assurance, permit a scheduled versus unscheduled maintenance action, permit increased critical system design flexibility and prevent cascading damage effects due to unmitigated failure of an electronic system. The system and methods described herein achieve these goals while minimizing required processing power and optimizing an amount of data sampled to available storage in the storage unit 62 and thus may be embedded in many new digital power supply systems with little to no design impact.

Although the description provided above relates generally to the rotorcraft 1, it is to be understood that this is merely exemplary and that the features of FIGS. 4-9 in particular are applicable to other types of aircraft and to other technologies.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A method for monitoring a health state of electronic equipment, comprising:
capturing data of an operation of the electronic equipment over a sampling range of predefined length;
storing captured data in a storage unit; and
characterizing a behavior of the operation of the electronic equipment based on an analysis of stored captured data in an event a predefined time has expired or the storage unit has reached maximum capacity.

2. The method according to claim 1, wherein the capturing comprises collecting current and voltage samples at an input and an output of a power supply of the electronic equipment.

3. The method according to claim 1, wherein the capturing comprises data sampling.

4. The method according to claim 1, wherein the capturing is conducted by sensors embedded in the electronic equipment.

5. The method according to claim 1, wherein the capturing is conducted by sensors disposed externally with respect to the electronic equipment.

6. The method according to claim 1, wherein the electronic equipment comprises a power converter.

7. The method according to claim 1, further comprising deferring the characterizing until the predefined time expires or the storage unit reaches the maximum capacity.

8. The method according to claim 1, wherein the characterizing comprises characterizing a behavior of input versus output power in the electrical equipment.

9. A method for monitoring a health state of electronic equipment of a rotorcraft, the method comprising:
capturing current and voltage samples from an input power and an output power of a power converter of the electronic equipment over a sampling range of predefined length;
storing data reflective of the captured current and voltage samples in a storage unit having a maximum capacity;
deferring a characterization of the stored data until a predefined time expires or the storage unit reaches the maximum capacity; and
characterizing a behavior of the input power and the output power based on an analysis of the stored data in an event the predefined time has expired or the storage unit has reached the maximum capacity.

10. The method according to claim 9, wherein the capturing is conducted by one or both of sensors embedded in the power converter and sensors disposed externally with respect to the power converter.

11. A rotorcraft, comprising:
an airframe on which main and auxiliary rotors are operably disposed to be drivable to rotate relative to the airframe to generate lift and thrust;
electronic equipment disposed about the airframe;
an electronic power supply disposed to provide electric power to the electronic equipment; and
a power supply control system coupled to the electronic power supply to control a provision of the electric power to the electronic equipment,
the power supply control system comprises a processing system to execute the method according to claim 1.

12. The rotorcraft according to claim 11, wherein the power supply control system comprises a power converter.

13. The rotorcraft according to claim 12, wherein the processing system is embedded in the power converter.

14. The rotorcraft according to claim 12, wherein the processing system is disposed externally with respect to the power converter.

15. The rotorcraft according to claim 1, wherein the processing system comprises a health and usage monitoring system (HUMS).
